(19) United States
(12) Patent Application Publication
(10) Pub. No.: US 2016/0177441 A1
(43) Pub. Date: Jun. 23, 2016

(54) Apparatus and Method of Manufacturing Free Standing CVD Polycrystalline Diamond Films

(71) Applicant: II-VI Incorporated, Saxonburg, PA (US)

(72) Inventors: David Sabens, Harmony, PA (US); Chao Liu, Butler, PA (US); Wen-Qing Xu, Medfield, MA (US); Charles D. Tanner, Saxonburg, PA (US)

(21) Appl. No.: 14/966,085

(22) Filed: Dec. 11, 2015

Related U.S. Application Data
(60) Provisional application No. 62/093,128, filed on Dec. 17, 2014.
(60) Provisional application No. 62/093,031, filed on Dec. 17, 2014.

(51) Int. Cl. C23C 16/27

(52) U.S. Cl. CPC C23C 16/274; C23C 16/276

(57) ABSTRACT

In a system and method of growing a diamond film, a cooling gas flows between a substrate and a substrate holder of a plasma chamber and a process gas flows into the plasma chamber. In the presence of an plasma in the plasma chamber, a temperature distribution across the top surface of the substrate and/or across a growth surface of the growing diamond film is controlled whereupon, during diamond film growth, the temperature distribution is controlled to have a predetermined temperature difference between a highest temperature and a lowest temperature of the temperature distribution. The as-grown diamond film has a total thickness variation (TTV)<10%, <5%, or <1%; and/or a birefringence between 0 and 100 nm/cm, 0 and 80 nm/cm, 0 and 60 nm/cm, 0 and 40 nm/cm, 0 and 20 nm/cm, 0 and 10 nm/cm, or 0 and 5 nm/cm.

### CROSS REFERENCE TO RELATED APPLICATIONS

This application claims the benefit of U.S. 62/093,128, filed Dec. 17, 2014, titled “Method of Manufacture of Free Standing CVD Polycrystalline Diamond Films with Low Birefringence”, and U.S. 62/093,031, filed Dec. 17, 2014, titled “Method of Manufacture of Free Standing CVD Polycrystalline Diamond Films Exhibiting Low Thickness Variation”, both of which are incorporated herein by reference.

### BACKGROUND OF THE INVENTION

1. Field of the Invention

The present invention is related to a method and apparatus for microwave plasma chemical vapor deposition growth of diamond films.

2. Description of Related Art

Polycrystalline diamond films have long been recognized for their unique combination of optical properties.

Presently, polycrystalline diamond films are grown on the industrial scale using a technique called chemical vapor deposition (CVD). Examples of prior art CVD growth techniques include: hot filament, DC arc jet, flame, and microwave plasma.

For Microwave Plasma CVD (MPCVD) diamond film growth, a diamond film growth substrate (in an example, made of W, Mo or Si) is loaded into a growth chamber in spaced relation to a cooling plate of the chamber, e.g., a water cooled base of the growth chamber, via stand-offs or spacers disposed between the substrate and the base of the chamber. Via a microwave generator source coupled to the growth chamber, a microwave plasma is generated above the substrate within the growth chamber flowing a technological or process gas of between 0.1-5% CH₄ in H₂ and, optionally, trace amounts of an inert gas, such as Ar or Ne, in the growth chamber, the interior of which is held, via a vacuum pump(s), at a pressure between 10-250 Torr (1.33-40 kPa) during growth of the diamond film on the substrate. The microwave energy supplied from the microwave generator source produces standing microwaves in the chamber with high-field and low-field regions. The growth chamber geometry can be configured such that a steady, high-electric-field node forms in close proximity to the surface of the substrate where diamond film growth occurs.

Within this high-electric field node, gas molecules of the technological or process gas absorb microwave energy breaking into reactive radicals and atoms thereby forming the plasma. The most abundant reactive species in this plasma are atomic hydrogen, H, and methyl radicals, CH_{3.} These gaseous species diffuse across the gas phase to the substrate surface, absorb on the substrate surface (or diamond film growing on the substrate surface), and participate in various reactions leading to nucleation and CVD growth of the diamond film on the substrate.

During MPCVD diamond film growth, the substrate is heated by the plasma to a temperature between 700-1200 degrees C. and the pressure inside the growth crucible is maintained between 10-250 Torr (1.33-40 kPa). Within this range of conditions, the diamond film phase is metastable. Upon attachment of methyl and other radicals to the substrate surface (or diamond film growing on the substrate surface), they form various bonds, including carbon-to-carbon diamond film-like sp³ bonds, graphite-like sp² bonds, as well as C—H bonds. In MPCVD diamond film 60 growth, atomic hydrogen plays two roles: it removes hydrogen from the growing diamond film by abstraction and it bonds to carbon and removes those carbon atoms that formed non-diamond film bonds from the growing diamond film.

One example of temperature control as a means to achieve uniform MPCVD diamond film growth is to flow a cooling gas to the backside of the substrate.

The use of spacers has been discussed, for example in U.S. Pat. No. 8,859,058, where the spacers are described as spacer wires or elements that “ . . . may be electrically conductive and/or may be fixed in place with an electrically conductive adhesive such as Silver DAG™ which has been found to be useful in ensuring a good electrical contact between the spacer elements and the substrate holder.”

Disadvantages of the use of electrically conductive spacer wires are three-fold: (1) the electrical conductivity of the spacer wires and/or the adhesive grounds the substrate and can cause non-uniformity of the plasma leading to growth rate/material quality variation; (2) the spacer wires made of electrically conductive material are of sufficiently high thermal conductivity that they can cause localized cooling of the substrate immediately above the spacer, resulting in high stress, low growth rate diamond film material locally above the spacer; and (3) the spacer wires reduce the flexibility of the growth chamber by removing the possibility of applying an electrical bias to the growth substrate.

### SUMMARY OF THE INVENTION

In a MPCVD reactor comprised of a resonance chamber that is comprised of a plasma chamber, an electrically conductive diamond growth substrate (in an example, made from W, Mo, or Si) is separated from an electrically conductive substrate holder that is intentionally cooled (in an example, via a cooling fluid, e.g., water, or via one or more thermoelectric coolers via the Peltier effect) by a uniform space or gap. In an example, this uniform gap is maintained by the use of three e.g., insulating spacers which can be placed, without adhesive, radially, 120 degrees apart on the chamber bottom or base. The diameter of the circle formed by the three evenly distanced spacers is selected to minimize effects of growth substrate sag on the cooling gap. The diameter (or largest dimension) of each spacer that is in contact with the bottom surface of the growth substrate can be between 0.1 and 2% of the diameter of the growth substrate. In an example, each spacer can have the same or a different diameter.

In another example, the uniform gap is maintained by the use of X insulating spacers which are placed, without adhesive, radially, (360 degrees/X) apart on the chamber bottom, where X is an integer ≧3.

In an example, ceramic is chosen as the material for the insulating spacers because ceramic is an electrical insulator and has low thermal conductivity, which minimizes the growth substrate and, hence, the growing diamond from experiencing temperature non-uniformity due to heat loss through a metal spacer or localized heating via an arc.

Resulting diamond films grown with such spacers exhibit thickness uniformity of >90%, or >95%, or >97%, or >99% across the entire substrate (as defined as 1 minus standard deviation of all measured points divided by average thickness)—which allows for better process predictability (through reduction in minimum growth rate variability by 50%) yield, and throughput.

Moreover, by actively controlling the combination of two or more of the following, the temperature distribution or profile between the center and the edge of the growing diamond can be maintained constant or substantially constant (in an example, ≧5° C., ≧3° C., or ≧1° C.) during the entire growth of the diamond film on the substrate: (1) the energy of microwave power delivered to the resonance chamber; (2) a pressure inside the plasma chamber; (3) a flow rate of the process gas into the plasma chamber; (4) a mixture of gases forming the process gas; (5) a percent composition of the gases forming the process gas; (6) a flow rate of the cooling gas; (7) a mixture of the gases forming the cooling gas; and (8) a percent composition of the gases forming the cooling gas.

In an example, by controlling two or more of (1)-(8) above, the temperature variation across the substrate (or diamond film growing on the substrate) can be reduced or maintained during diamond film growth to within 1% and the thickness of the grown diamond film can vary less than 5%. In an example, the temperature variation can be measured via one or more optical pyrometers.

In an example, achieving and maintaining throughout the entire MPCVD diamond film growth cycle a uniform temperature distribution across the substrate (or diamond film growing on the substrate) yields a freestanding polycrystalline diamond film with spatially uniform properties, including low and spatially uniform birefringence. In an example, a freestanding diamond film grown in accordance with the principles described herein can have a measured birefringence in the range between at least one of the following: 0 and 100 nm/cm; 0 and 80 nm/cm; 0 and 60 nm/cm; 0 and 40 nm/cm; 0 and 20 nm/cm; 0 and 10 nm/cm; or 0 and 5 nm/cm.

In an example, a freestanding diamond film grown in accordance with the principles described herein can be crack-free, can have a diameter of >120 mm, or >140 mm, or >160 mm, or >170 mm, and can have a thickness between 150 μm and about 3.3 mm.

Moreover, the freestanding diamond film grown in accordance with the principles described herein can exhibit low residual stress leading to low deformation during post-growth processing. The freestanding diamond film grown in accordance with the principles described herein can be suitable for the fabrication of high quality polished optical windows with the diameter between 70 mm and 160 mm and thickness between 100 μm and 3.0 mm.

Various preferred and non-limiting examples or aspects of the present invention will now be described and set forth in the following numbered clauses:

Clause 1: A microwave plasma reactor for the growth of diamond film by microwave plasma assisted chemical vapor deposition comprises: a resonance chamber made of an electrically conductive material; a microwave generator coupled to feed microwaves into the resonance chamber; a plasma chamber comprising part of the resonance chamber interior space and separated from the remainder of the resonance chamber by a gas-impermeable dielectric window; a gas control system for supplying a process gas and a cooling gas into the plasma chamber, removing gaseous byproducts from the plasma chamber, and for maintaining the plasma chamber at a lower gas pressure than the remainder of the resonant chamber; an electrically conductive and cooled substrate holder disposed at the bottom of the plasma chamber; and an electrically conductive substrate for growing diamond film on a top surface of the substrate that faces away from the substrate holder, wherein the substrate is disposed in the plasma chamber parallel to the substrate holder, the substrate is spaced from the substrate holder by a gap having a height d, the substrate is electrically insulated from the substrate holder, the gas control system is adapted to supply the process gas into the plasma chamber between the dielectric window and the substrate, and the gas control system is adapted to supply the cooling gas into the gap.

Clause 2: The reactor of clause 1, further including one or more pyrometers positioned for measuring one or more temperatures of the substrate; and a process control system operative for controlling two or more of the following based on a temperature of the substrate measured by the one or more pyrometers: (1) the energy of microwave power delivered to the resonance chamber, (2) a pressure inside the plasma chamber, (3) a flow rate of the process gas into the plasma chamber, (4) a mixture of gases forming the process gas, (5) a percent composition of the gases forming the process gas, (6) a flow rate of the cooling gas, (7) a mixture of the gases forming the cooling gas, and (8) a percent composition of the gases forming the cooling gas.

Clause 3: The reactor of clause 1 or 2, wherein the substrate holder either comprises part of the bottom of the plasma chamber or is separate from the bottom of the plasma chamber.

Clause 4: The reactor of any of clauses 1-3, wherein the gas control system comprises: a source of the process gas; a source of vacuum for maintaining the plasma chamber at the lower gas pressure than the remainder of the resonant chamber; and a source of the cooling gas.

Clause 5: The reactor of any of clauses 1-4, wherein at least one of the following: the process gas includes a mixture of gaseous CH₄ and gaseous H₂; and the cooling gas includes one or more of the following gases: H₂, He, Ar, and Xe.

Clause 6: The reactor of any of clauses 1-5, wherein the substrate is spaced from the substrate holder by electrically nonconductive spacers.

Clause 7: The reactor of any of clauses 1-6, wherein an end of each spacer has the form of a disc, a rectangle or square, or a triangle.

Clause 8: The reactor of any of clauses 1-7, wherein there is a minimum of 3 spacers.

Clause 9: The reactor of any of clauses 1-8, wherein an area of each spacer in contact with a bottom surface of the substrate that faces the substrate holder is <0.01% of a total surface area of the bottom surface of the substrate.

Clause 10: The reactor of any of clauses 1-9, wherein a total area of the spacers in contact with a bottom surface of the substrate that faces the substrate holder is <1% of the total surface area of the bottom of the substrate.

Clause 11: The reactor of any of clauses 1-10, wherein the spacers are distributed whereupon cooling gas flowing in the gap between the substrate holder and substrate has a Reynold's number of <1 such that the cooling gas flow is laminar. Herein, and as is known in the art, Reynold's number is a dimensionless variable used to predict flow profiles for any fluid, fluid speed and cavity size. It is defined as a ratio between inertial forces (flow rate, chamber dimensions) and viscosity. Herein, a Reynold's number <1 assures that the flow of cooling gas in the gap between the substrate and substrate holder remains unperturbed as it passes around the spacers.

Clause 12: The reactor of any of clauses 1-11, wherein the spacers are made of a material having an electric resistivity >1×10⁵ Ohm-cm at 800° C.

Clause 13: The reactor of any of clauses 1-12, wherein the spacers made of ceramic.

Clause 14: The reactor of any of clauses 1-13, wherein the spacers are made of a material belonging to the group of at least one of the following: oxides, carbides and nitrides.

Clause 15: The reactor of any of clauses 1-14, wherein the spacers made of aluminum oxide (Al₂O₃).

Clause 16: The reactor of any of clauses 1-15, wherein the spacers have a thermal conductivity between one of the following: 1-50 W/m K; 10-40 W/m K; or 25-35 W/m K.

Clause 17: The reactor of any of clauses 1-16, wherein at least one of the following: each spacer is positioned between 50-80% of a radius of the substrate; the spacers are distributed along a circumference of a single radius of the substrate; and between a center of the substrate and the position of each spacer between the substrate and the substrate holder, a Reynolds number of the cooling gas flow through the gap is one of the following: <1; or <0.1; or <0.01.

Clause 18: The reactor of any of clauses 1-17, wherein the spacers have a total cross-sectional area that is <1%, or <0.1%; or <0.01% of a cross-sectional area of the substrate.

Clause 19: The reactor of any of clauses 1-18, wherein the height d of the gap between the substrate and the substrate holder is one of the following: between 0.001% and 1% of the substrate diameter, or between 0.02% and 0.5% of the substrate diameter.

Clause 20: A method of growing a diamond film in the plasma reactor of any of clauses 1-19 comprising: (a) providing the cooling gas into the gap between the substrate and the substrate holder; (b) providing the process gas into the plasma chamber; (c) supplying to the resonant chamber microwaves of sufficient energy to cause the process gas to form in the plasma chamber a plasma that heats a top surface of the substrate to an average temperature between 750° C. and 1200° C.; and (d) in the presence of the plasma in the plasma chamber, actively controlling a temperature distribution across the top surface of the substrate and/or across a growth surface of the diamond film growing on the top surface of the substrate in response to the plasma such that the temperature distribution has less than a predetermined temperature difference between a highest temperature of the temperature distribution and a lowest temperature of the temperature distribution.

Clause 21: The method of clause 20, wherein the temperature distribution is controlled such that the as-grown diamond film has at least one of the following: a total thickness variation (TTV) <10%, <5%, or <1%; and a birefringence between 0 and 100 nm/cm between 0 and 80 nm/cm, between 0 and 60 nm/cm, between 0 and 40 nm/cm, between 0 and 20 nm/cm, between0 and 10 nm/cm, or between 0 and 5 nm/cm. The birefringence can be measured at a wavelength of 632.8 nm.

Clause 22: The method of clause 20 or 21, wherein actively controlling the temperature distribution includes controlling at least two of the following: (1) the energy of microwave power delivered to the resonance chamber; (2) a pressure inside the plasma chamber; (3) a flow rate of the process gas into the plasma chamber; (4) types of gases forming the process gas; (5) a percent composition of the gases forming the process gas; (6) a flow rate of the cooling gas; (7) types of the gases forming the cooling gas; and (8) a percent composition of the gases forming the cooling gas.

Clause 23. The method of any of clauses 20-22, wherein at least one of the following: the temperature distribution is measured between a center and an edge of the top surface of the substrate, or between a center and an edge of the growth surface of the growing diamond film, or both; and the predetermined temperature difference between the highest and lowest temperatures of the temperature distribution is measured at the center and the edge of the top surface of the substrate, or between the center and the edge of the growth surface of the growing diamond film, or both.

Clause 24. The method of any of clauses 20-23, wherein the predetermined temperature difference between the highest temperature and the temperature of the temperature distribution is <1° C.

Clause 25. The method of any of clauses 20-24, wherein the predetermined temperature difference between the highest temperature and the temperature of the temperature distribution is <5° C.

Clause 26. The method of any of clauses 20-25, wherein the predetermined temperature difference between the highest temperature and the lowest temperature of the temperature distribution is <10° C.

### BRIEF DESCRIPTION OF THE DRAWINGS

FIG. 1 is a first example MPCVD reactor including a fluid cooled substrate holder comprising a base of the reactor;

FIG. 2 is a second example MPCVD reactor including a fluid substrate holder supported by a base of the reactor;

FIG. 3 is a third example MPCVD reactor including a thermoelectric module(s) cooled substrate holder comprising a base of the reactor;

FIG. 4 is a fourth example MPCVD reactor including a thermoelectric module(s) cooled substrate holder supported by a base of the reactor;

FIG. 5 is an isolated plan view of three spacers positioned under a phantom view of the substrate shown in any one of FIGS. 1-4; and

FIGS. 6A-6C are perspective views of different shaped spacers that can be positioned between the substrate the substrate holder in any one of FIGS. 1-4.

### DESCRIPTION OF THE INVENTION

Various non-limiting examples will now be described with reference to the accompanying figures where like reference numbers correspond to like or functionally equivalent elements.

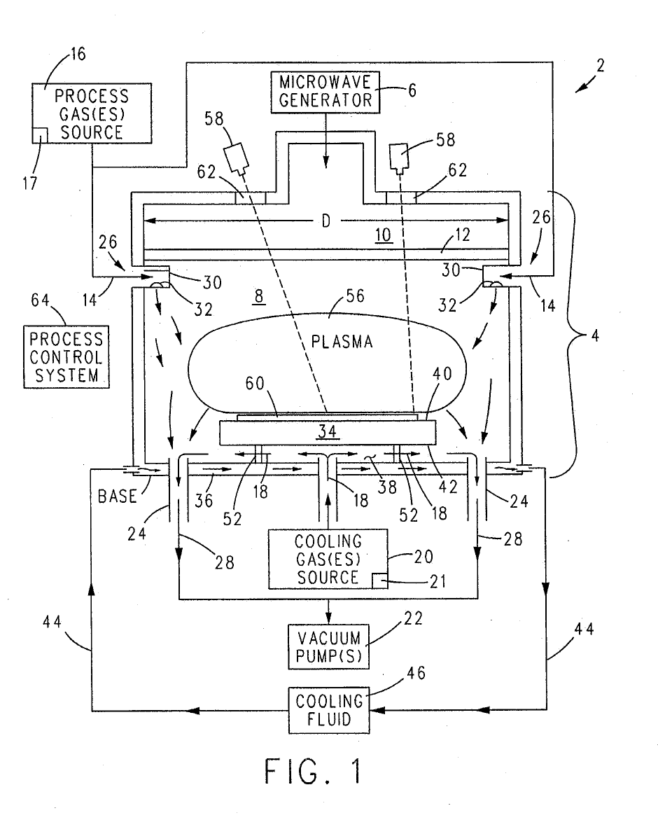

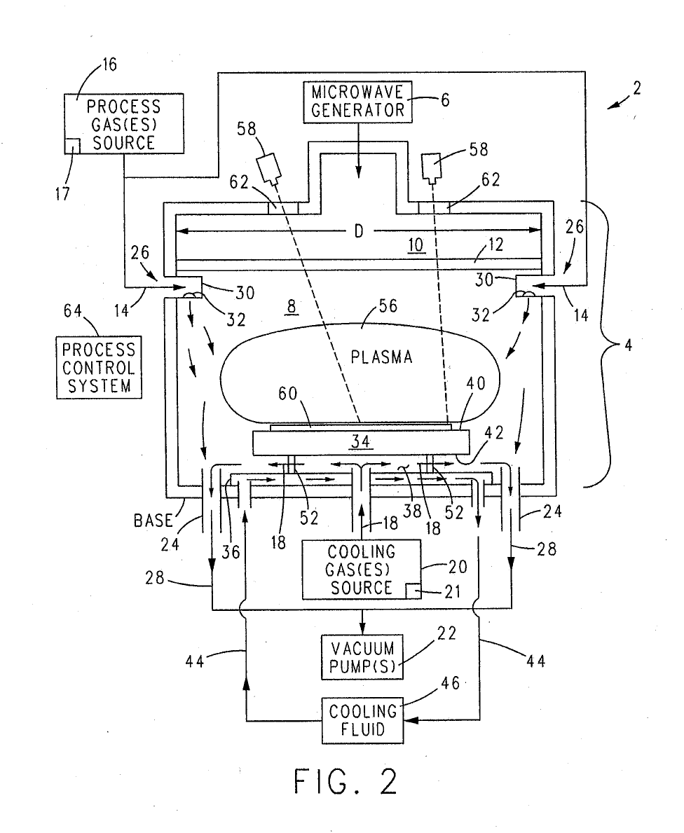

FIGS. 1-4 are respective first through fourth example MPCVD reactors 2, wherein the second through fourth example MPCVD reactors 2 shown in FIGS. 2-4, respectively, are in most respects similar to the first example MPCVD reactor 2 shown in FIG. 1. Accordingly, except as discussed hereinafter to highlight differences between first through fourth example MPCVD reactors 2, the following description will: (1) be with specific reference to the first example MPCVD reactor 2 shown in FIG. 1, (2) will apply equally to the second through fourth example MPCVD reactors 2 shown in FIGS. 2-4, respectively, and, (3) specific descriptions of like or functionally equivalent elements of the second through fourth example reactors 2 shown in FIGS. 2-4 will not be described to avoid unnecessary redundancy.

In general, during MPCVD growth, precise control of temperature uniformity can be ensured through the use of a growth substrate made of, for example, W, Mo, or Si of diameter ranging, in an example, from 100-180 mm with surface planarity in the range of, in an example, ±2.5 μm on both top and bottom surfaces. The top and bottom surfaces of the growth substrate can also be parallel (variation in the measured distance between the top and bottom surface across the entire substrate) with thickness variation, in an example, ±5 μm. The growth substrate can be precisely offset from the chamber bottom via insulating (e.g., without limitation, ceramic) spacers with a substrate/chamber bottom gap with a variation of, in an example, ±5 μm across the entire gap to ensure uniform thermal mass, uniform cooling rates across the entire substrate, or both.

Referring to FIG. 1, the first example MPCVD reactor 2 can include a resonance chamber 4 made of electrically conductive material. A microwave generator 6 can be coupled to feed microwaves into resonance chamber 4. In a non-limiting example, microwave generator 6 can be coupled to feed microwaves into a top of resonance chamber 4.

A plasma chamber 8 comprises a part (in an example, a lower part) of an interior space of resonance chamber 4 that is separated from a remainder 10 (in an example, an upper part) of resonance chamber 4 via a gas-impermeable dielectric window 12. In a non-limiting example, resonance chamber 4 and, hence, plasma chamber 8 can be cylindrical with a diameter D.

Reactor 2 includes a gas control system for supplying into plasma chamber 8 a process gas 14 from a process gas(es) source 16 and a cooling gas 18 from a cooling gas(es) source 20. Process gas(es) source 16 and cooling gas(es) source 20 can include flow controllers 17 and 21, respectively, for enabling the flow rates of process gas 14 and cooling gas 20 to be individually controlled.

Process gas 14 can be supplied into plasma chamber 8 via one or more ports 26 disposed in: (1) a wall of plasma chamber 8 (shown in FIG. 1) and/or (2) in dielectric window 12 (not shown in FIG. 1). In an example, the one or more ports 26 can feed process gas 14 directly into plasma chamber 8. In another example, the interior of plasma chamber 8 can include an optional gas distribution manifold 30 at or near the top of plasma chamber 8 that is coupled in fluid communication with the one or more ports 26. Gas distribution manifold 30 can include one or more nozzles or openings 32 oriented to direct process gas 14 in a desired direction inside of plasma chamber 8, for example, direct process gas 14 toward a base of plasma chamber 8. In a non-limiting example, manifold 30 can have an annular shape.

Gas control system also includes a source of vacuum or vacuum pump(s) 22, such as a mechanical and/or turbomolecular vacuum pump, coupled to plasma chamber 8 via one or more ports 24. In a non-limiting example, the one or more ports 24 can be through the base of plasma chamber 8. In operation, vacuum pump(s) 22 acts in a manner known in the art to evacuate the interior of plasma chamber 8, remove gaseous byproducts 28 from plasma chamber 8, and maintain plasma chamber 8 at a lower gas pressure than the remainder 10 of resonance chamber 4 and an exterior of resonance chamber 4. In an example, vacuum pump(s) 22 can act to control the pressure inside of plasma chamber 8 to be in a range between 10 Torr (1.33 kPa) and 300 Torr (40 kPa).

Reactor 2 further includes a substrate 34 spaced above a cooled substrate holder 36 via a gap 38. In an example, the one or more ports 26 and/or manifold 30 can feed process gas 14 directly into plasma chamber 8 between dielectric window 12 and a substrate 34.

In the first example reactor 2 shown in FIG. 1, substrate holder 36 can comprise the base of plasma chamber 8. In the second example reactor 2 shown in FIG. 2, substrate holder 36 can be an element separate from the base of plasma chamber 8 and can either rest on the base of plasma chamber 8 (as shown) or can be spaced by standoffs from the base of plasma chamber 8. In the first and second example reactors 2 shown in FIGS. 1 and 2, a cooling fluid source 46 supplies a suitable cooling fluid 44, for example, water, to an interior of substrate holder 36 to cool substrate holder 36 during growth of a diamond film 60 on a top surface 40 of substrate 34.

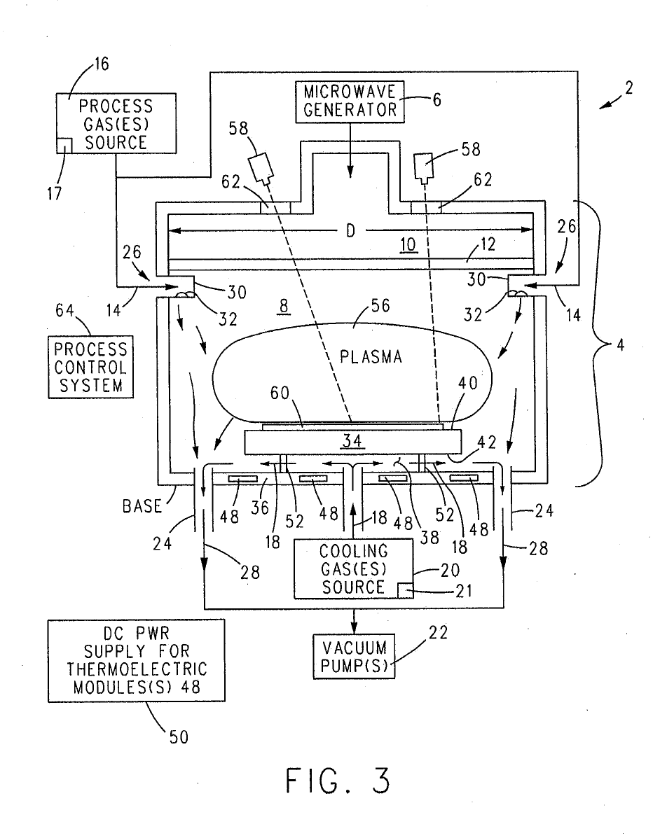

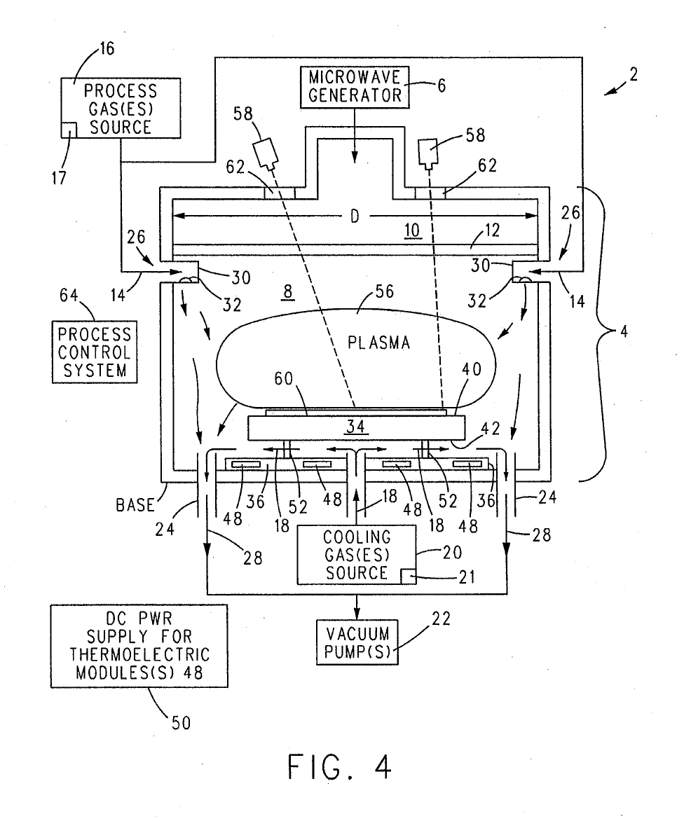

In the third and fourth example reactors 2 shown in FIGS. 3 and 4, cooling fluid 44 and cooling fluid source 46 in the first and second example reactors 2 shown in FIGS. 1 and 2 can be replaced with one or more thermoelectric modules 48 that cool substrate holders 36 via the Peltier effect upon application of DC power to the one or more thermoelectric modules 48 from a DC power supply 50.

The cooling of substrate holder 36 during the growth of diamond film 60 on substrate 34 aids in the removal of unwanted heat from substrate 34 and, hence, diamond film 60 growing on substrate 34. This removal of heat facilitates the CVD growth of diamond film 60 of high-quality.

In an example, substrate 34 can have a diameter in a range between 100 mm and 180 mm, a thickness in a range between 8 mm and 14 mm, and planarity in the range of ±2.5 μm on both the top surface 40 and a bottom surface 42 of substrate 34. Top and bottom surfaces 40, 42 of substrate 34 are also parallel (variation in the measured distance between top and bottom surfaces 40, 42 across the entirety of substrate 42) in the range of ±5 μm.

In an example, substrate 34 can be positioned with fixed gap 38 of height d between 50 μm and 1000 μm and with a variation of ±5 μm across the entirety of gap 38 above substrate holder 36, which can be held at a desired temperature ±2° C. via cooling fluid 44 (first and second example reactors 2 shown in FIGS. 1 and 2) or one or more thermoelectric modules 48 (third and fourth example reactors 2 shown in FIGS. 3 and 4). Where cooling fluid 44 is used to cool substrate holder 36, the temperature of cooling fluid 44 exiting substrate holder 36 can be measured. Based on the measured temperature of cooling fluid 44 exiting substrate holder 36, the volume and/or temperature of cooling fluid 44 supplied to substrate holder 36 can be adjusted as needed to maintain substrate holder 36 at a fixed temperature.

In one non-limiting example, gap 38 can be achieved via a minimum of three insulating (e.g., ceramic) spacers 52 of thickness between 50 μm and 1000 μm disposed between and, in an example, in direct contact with substrate 34 and substrate holder 36. In an example, the heights of all of spacers 52 can be ≦2 μm of each other. In an example, spacers 52 can be made of a material having an electric resistivity >1×10⁵ Ohm-cm at 800° C. One example of a material that can be used to make spacers 52 is ceramic. In another example, spacers 52 can be of a material belonging to the group of at least one of the following: oxides, carbides and nitrides. In another example, spacers can be made of aluminum oxide (Al₂O₃). In an example, spacers 52 can have a thermal conductivity between one of the following: 1-50 W/m K; 10-40 W/m K; or 25-35 W/m K.

In another example, each spacer 52 can be positioned between 50-80% of a radius of the substrate 34; and/or spacers 52 can be distributed along a circumference of a single radius of substrate 34; and/or between a center 52 of substrate 34 and the position of each spacer 52 between substrate 34 and substrate holder 35, a Reynolds number of cooling gas 18 flow through gap 38 is one of the following: <1; or <0.1; or <0.01.

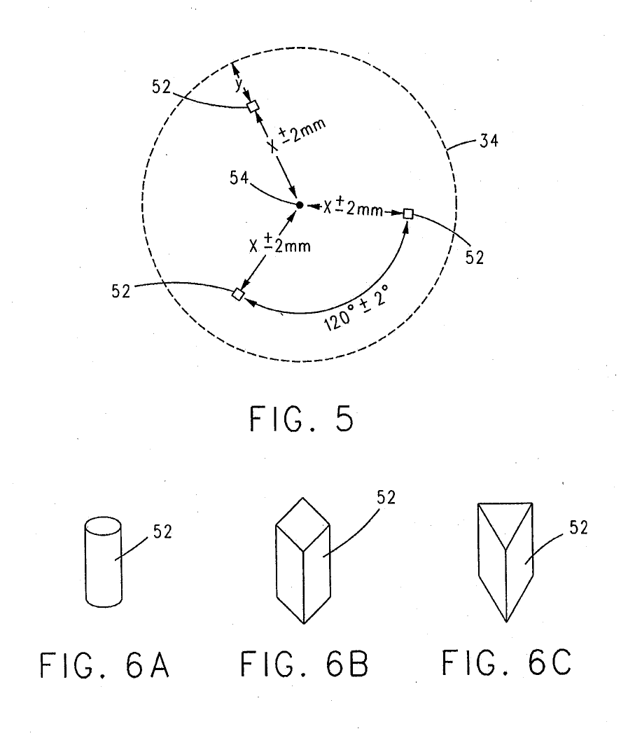

In an example, spacers 52 can be disposed equidistant apart (distance x) from a center 54 of substrate 34 (FIG. 5). Gap 38 can be maintained by the use of X number of spacers 52 which are placed, without adhesive, radially (360 degrees/X spacers 52) apart between substrate 34 and substrate holder 36, wherein X (spacers 52) is an integer >3. In an example, where X spacers 52 are provided, these X spacers 52 can be placed about 360 degrees/X ±2 degrees apart and, in an example, equidistant ±2 mm from center 54 of substrate 34 as shown in the attached FIG. 5. In another example, each spacer 52 can be placed equidistant ±2% of the radius of the growth substrate 34. In another example, each spacer 52 can be placed ≧50% of the radius of growth substrate 34 and ≦80% of the radius of growth substrate 34. Each spacer 52, in cross-section, can have a have the form of a disc (FIG. 6A), a rectangle or square (FIG. 6B), or a triangle (FIG. 6C). Via spacers 52, substrate 34 can be electrically insulated from substrate holder 36.

In an example, an area of each spacer in contact with bottom surface 42 of the substrate 34 that faces substrate holder 36 is <0.01% of a total surface area of bottom surface 42 of substrate 34. In an example, a total area of all of the spacers 52 in contact with bottom surface 42 of substrate 34 that faces substrate holder 36 is <1% of the total surface area of bottom surface 42 of substrate 34. In another example, a total cross-sectional area of spacers 52 between substrate 34 and substrate holder 36 can be <1%, or <0.1%; or <0.01% of a cross-sectional area of substrate 34.

In an example, all of spacers 52 are distributed between substrate 34 and substrate holder 36 and cooling gas 18 flowing in gap 38 is controlled in a manner whereupon cooling gas 18 flowing in gap 38 between substrate 34 and substrate holder 36 has a Reynold's number of <1 such that the flow of cooling gas in gap 38 is laminar.

In an example, the height d of gap 38 between substrate 34 and substrate holder 36 can be one of the following: between 0.001% and 1% of the diameter of substrate 34, or between 0.02% and 0.5% of the diameter of substrate 34.

As can be seen, plasma chamber 8, where CVD growth of diamond film 60 occurs, is a subset of resonance chamber 4 which is configured to co-act with the frequency of microwaves supplied by microwave generator 6 to form a steady, high-electric-field node in close proximity to top surface 40 of substrate 34 where diamond film 60 growth occurs. Hence, during growth of diamond film 60, microwaves can be present in remainder 10 of resonance chamber 4 which is not exposed to the low pressure produced by vacuum pump(s) 22 in plasma chamber 8. Benefits of having plasma chamber 8 be a subset of resonance chamber 4 can include, without limitation, one or more of the following: (1) the volume of plasma chamber 8 can optimized for the growth of diamond film 60, (2) better control over the flow and/or distribution of process gas 14 in plasma chamber 8, (3) better control over the flow and/or distribution of cooling gas 18 in gap 38, (4) better control of the pressure inside of plasma chamber 8 during growth of diamond film 60, and/or (5) the volume of resonance chamber 4 can be optimized to form a steady, high-electric-field node in close proximity to top surface 40 of substrate 34 where diamond film 60 growth occurs while, concurrently, the volume of plasma chamber 8 can optimized for any other reason, e.g., any one or more of benefits (1)-(4) above.

A method of growing a diamond film in one of first-fourth plasma reactors 2 shown in FIGS. 1-4 will be now described.

In the method, cooling gas 18 can be provided to gap 38 between substrate 34 and substrate holder 36 and process gas 14 can be provided to plasma chamber 8. Microwaves of suitable and/or desirable power and frequency can be introduced into resonance chamber 4 that cause process gas 14 to form in plasma chamber 8 a plasma 56 that heats top surface 40 of substrate 34 to an average temperature between 750° C. and 1200° C. In the presence of plasma 56 in plasma chamber 8, a temperature distribution across top surface 40 of substrate 34 and/or across a growth surface of diamond film 60 growing on the top surface of substrate 34 in response to plasma 56 can be controlled such that the temperature distribution has less than a predetermined temperature difference between a highest temperature of the temperature distribution and a lowest temperature of the temperature distribution. In an example, the predetermined temperature difference between the highest temperature and the temperature of the temperature distribution can be <10° C., <5° C., or <1° C.

The temperature distribution can be controlled such that the as-grown diamond film 60 can have at least one of the following: a total thickness variation (TTV) <10%, <5%, or <1%; and/or a birefringence between 0 and 100 nm/cm, between 0 and 80 nm/cm, between 0 and 60 nm/cm, between 0 and 40 nm/cm, between 0 and 20 nm/cm, between 0 and 10 nm/cm, or between 0 and 5 nm/cm. In an example, the birefringence can be measured at a wavelength of 632.8 nm.

The step of actively controlling the temperature distribution can include controlling at least two of the following: (1) the energy of microwave power delivered to the resonance chamber; (2) a pressure inside the plasma chamber; (3) a flow rate of the process gas into the plasma chamber; (4) types of gases forming the process gasses; (5) a percent composition of the gases forming the process gasses; (6) a flow rate of the cooling gas; (7) types of the gases forming the cooling gas; and (8) a percent composition of the gases forming the cooling gas.

The temperature distribution can be measured at or between a center and an edge of top surface 40 of substrate 34, at or between a center and an edge of the growth surface of the growing diamond film 60 as it grows on the top surface 40 of substrate 34, or both. The predetermined temperature difference between the highest and lowest temperatures of the temperature distribution can be measured at the center and the edge of top surface 40 of substrate 34, or between the center and the edge of the growth surface of the growing diamond film 60 as it grows on the top surface 40 of substrate 34, or both.

More specifically, at an appropriate time, suitable growth conditions can be established and maintained in plasma chamber 8 for the MPCVD growth of diamond film 60. Examples of such suitable growth conditions include introducing process gas 14 and cooling gas 18 into plasma chamber 8 in the presence of vacuum pump(s) 22 evacuating plasma chamber 8 to a desired diamond film 60 growth pressure, for example, between 10 Torr (1.33 kPa) and 300 Torr (40 kPa). In a non-limiting example, process gas 14 can be comprised of hydrogen with between 0.1 and 2% Methane and a trace amount of inert gas, in an example Ar or Ne. The total flow rate of process gas 14 introduced into plasma chamber 8 can be between 1200 and 2500 sccm. Microwaves of a single frequency within the range between 300 MHz and 1500 MHz and a delivered power of between 10 kW and 30 kW can be introduced by microwave generator 6 into resonance chamber 4 to form from process gas 14 plasma 56 above top surface 40 of substrate 34.

Cooling gas 18 can be a gas mixture comprised of varying proportions of H₂, He, Ar, and/or Ne controlled based on a desired thermal conductivity of cooling gas 18 introduced into gap 38 in order to target appropriate growth temperatures (e.g., between 750° C. and 1200° C.) on top surface 40 of substrate 34, or on the growth surface of diamond film 60 growing on top surface 40 of substrate 34, or both. During CVD growth of diamond film 60 on top surface 40 of substrate 34, vacuum pump(s) 22 act(s) to maintain plasma chamber 8 at the desired diamond film 60 growth pressure.

Temperatures of top surface 40 of substrate 34 and/or of diamond film 60 growing on top surface 40 can be measured by one or more pyrometers 58 via one or more windows 62 of reactor 2 and dielectric window 12. In an example, one pyrometer 58 can measure the temperature at or near the center of top surface 40 of substrate 34 and, during the growth of diamond film 60, the portion of diamond film 60 growing at or near the center of top surface 40 of substrate 34. In an example, another pyrometer 58 can measure the temperature at or near an edge of top surface 40 of substrate 34 and, during the growth of diamond film 60, the portion of diamond film 60 growing at or near the edge of top surface 40 of substrate 34.

During growth of diamond film 60 on substrate 34 using one of the example reactors 2 shown in FIGS. 1-4, a difference between the center temperature and the edge temperature of substrate 34 and/or diamond film 60 growing on substrate 34 can be controlled within the range ≦5° C., ≦3° C., or ≦1° C. More specifically, each example reactor 2 shown in FIGS. 1-4 can include a software controlled, computer or microprocessor based process control system 64, such as, for example, without limitation, a programmable logic controller (plc) commercially available from, for example, Rockwell Automation of Milwaukee, Wis., USA. Process control system 64 can be operative for controlling two or more of the following based on one or more temperatures of substrate 34 and/or diamond film 60 growing on substrate 34 measured by the one or more pyrometers 58: (1) an energy of microwave power delivered by microwave generator 6 to resonance chamber 4; (2) a gas pressure inside of plasma chamber 8; (3) a flow rate of process gas 14 into plasma chamber 8; (4) the mixture of gases forming process gas 14; (5) a percent composition of gases forming process gas 14; (6) a flow rate of cooling gas 18 in gap 38; (7) a mixture of the gases forming cooling gas 18; and (8) a percent composition of the gases forming cooling gas 18.

Hereinafter, unless otherwise indicated or apparent from the disclosure, it will assumed that suitable growth condition(s) (including (i) the flow rate and/or percent composition of process gas 14, and/or (ii) the flow rate and/or percent composition of cooling gas 18, and/or (iii) the delivered microwave power and/or frequency) have been established in plasma chamber 8 and that the growth of diamond film 60 on substrate 34 has commenced. More specifically, unless otherwise indicated or apparent from the disclosure, it will be assumed that the growth condition(s) have been established such that temperatures at a center and an edge of substrate 34 and diamond film 60 growing on substrate 34 have been set that establish a desired temperature distribution or temperature profile between the center and the edge. In an example the desired temperature distribution or temperature profile between the center and the edge of substrate 34 and diamond film 60 growing on substrate 34 is set within the range ≦5° C., ≦3° C., or ≦1° C.

In an example, process control system 64 can adjust the flow rate of process gas 14 delivered via the one or more ports 26 based on temperatures, especially temperature differences, at the center and an edge of substrate 34 and diamond film 60 growing on substrate 34 (each temperature determined via a pyrometer 58) to maintain the desired temperature distribution or temperature profile between the center and the edge of substrate 34 within the range ≦5° C., ≦3° C., or ≦1° C. For example, if plasma 56 heats the center of substrate 34 or diamond film 60 growing on substrate 34 more than the edge thereof,' process control system 64 can automatically adjust (increase) the flow rate of process gas 14 delivered via ports 26 to decrease the temperature at the center and, hence, reduce or minimize the temperature difference between the center and the edge.

In another example, if process control system 64 determines via one or more pyrometers 58 that the center of substrate 34 or diamond film 60 growing on substrate 34 is cooler than the edge thereof, process control system 64 can adjust (reduce) the flow rate of process gas 14 delivered via the one or more ports 26 to increase the temperature at the center and, hence, reduce or minimize the temperature difference between the center and the edge.

In a more specific example, process control system 64 can continuously or periodically monitor (via one or more pyrometers 58) the center and edge temperatures of substrate 34 or diamond film 60 growing on substrate 34 and, in response to said monitored center and edge temperatures, dynamically adjust or vary the flow rate of process gas 14 delivered via the one or more ports 26 in a manner that reduces or minimizes the temperature difference between the center and the edge. In an example, process gas 14 delivered via the one or more ports 26 can be varied (increased and/or decreased) in a step function or a continuous ramp in order to undo any shift in the temperature at the center and/or the edge of the substrate 34 and/or diamond film 60 growing on substrate 34.

Hereinafter, references to center temperature and edge temperature without specific reference to substrate 34 or diamond film 60 growing on substrate 34 are to are to be understood as the center temperature and edge temperatures of substrate 34 and, as diamond film 60 grows on substrate 34, the growing diamond film 60.

In a generalized example, reducing the flow rate of process gas 14 reduces the edge temperature relative to the center temperature and increasing the flow rate of process gas 14 increases the edge temperature relative to the center temperature. More specifically, reducing the flow rate of process gas 14 increases the center and edge temperatures, but increases the edge temperature to a lesser extent than the center temperature. Conversely, increasing the flow rate of process gas 14 decreases the center and edge temperatures, but decreases the edge temperature to a lesser extent than the center temperature.

Moreover, adjusting the magnitude of the delivered microwave power can affect the temperature at the center of diamond film 60 growing on substrate 34. In an example, reducing the magnitude of the delivered microwave power increases the edge temperature relative to the center temperature, and increasing the magnitude of the delivered microwave power reduces the edge temperature relative to the center temperature. More specifically, reducing the magnitude of the delivered microwave power decreases the edge and center temperatures, but decreases the edge temperature to a greater extent than the center temperature. Conversely, increasing the magnitude of the delivered microwave power increases the edge and center temperatures, but increases the edge temperature to a greater extent than the center temperature.

In another example, process control system 64 can continuously or periodically monitor the center and edge temperatures (via one or more pyrometers 58) and, in response to said monitored center and edge temperatures, dynamically adjust or vary the magnitude of the delivered microwave power in a manner that reduces or minimizes the temperature difference between the center and the edge.

The use of two optical pyrometers 58 is described above for measuring temperatures at the center and the edge of the diamond film 60 growing on substrate 34. However, for the reasons discussed next, this is not to be construed in a limiting sense.

In yet another example, it has been observed that once the center and edge temperatures are established and, hence, the temperature distribution or profile between the center and the edge of substrate 34 and/or diamond film 60 growing on substrate 34 is established, the temperature at the center (or edge) and, hence, the temperature distribution or profile can be maintained constant or substantially constant by monitoring and controlling only the center (or edge) temperature. In this regard, it has been observed that minor changes in one or more of (1) the energy of microwave power delivered by microwave generator 6 to resonance chamber 4; (2) the gas pressure inside of plasma chamber 8; (3) the flow rate of process gas 14 into plasma chamber 8; (4) the mixture of gases forming process gas 14; (5) the percent composition of gases forming process gas 14; (6) the flow rate of cooling gas 18 in gap 38; (7) the mixture of the gases forming cooling gas 18; and (8) the percent composition of the gases forming cooling gas 18, can change the center (or edge) temperature while maintaining the temperature distribution or profile between the center and the edge constant or substantially constant.

In an example, by increasing the flow rate of process gas 14 in response to the temperature at the center (or edge) decreasing during the growth of diamond film 60 on substrate 34, the temperature at the center (or edge) can be controlled to be constant or substantially constant and, hence, the temperature distribution or profile between the center and the edge can be controlled to be constant or substantially constant. As used herein, a temperature or temperature distribution or profile is “substantially constant” if it is within ±2% of the highest temperature in degrees C.

In an example, process control system 64 can adjust the flow rate and/or the percent composition of gasses forming cooling gas 18 to change the baseline temperature of diamond film 60 growing on substrate 34. In an example, cooling gas 18 is comprised of a mixture of two or more of the following gasses, each of which has different thermal conductivities at different pressures and temperatures: H₂, He, Ar, and Ne. Thus, the thermal conductivity of cooling gas 18 at a particular temperature and pressure is based on the percent mixture of the gases forming cooling gas 18. By selectively adjusting the mixture of gasses forming cooling gas 18, process control system 64 can adjust the thermal conductivity of cooling gas 18 and, hence, the baseline temperature of diamond film 60 growing on substrate 34.

In an example, the flow rate of cooling gas 18 can be adjusted to adjust the baseline temperature of diamond film 60 growing on substrate 34, e.g., a higher flow rate of cooling gas 18=a lower baseline temperature, while a lower flow rate of cooling gas 18=a higher baseline temperature. Of course combinations of adjusting the mixture of gasses forming cooling gas 18 and the flow rate of cooling gas 18 to control the baseline temperature is envisioned.

It has been observed that adjusting the flow rate and/or thermal conductivity of cooling gas 18 can, to a small extent, raise or lower the edge temperature with respect to the center temperature. In an example, adjusting the flow rate and/or thermal conductivity of cooling gas 18 is principally used to shift the entire temperature distribution or profile up or down in temperature as a response to other changes, such as the growth of diamond film 60 over time, changes in flow rate of process gas 14, and/or changes in delivered microwave power.

In another example, two or more of (1) the energy of microwave power delivered by microwave generator 6 to resonance chamber 4; (2) the gas pressure inside of plasma chamber 8; (3) the flow rate of process gas 14 into plasma chamber 8; (4) the mixture of gases forming process gas 14; (5) the percent composition of gases forming process gas 14; (6) the flow rate of cooling gas 18 in gap 38; (7) the mixture of the gases forming cooling gas 18; and (8) the percent composition of the gases forming cooling gas 18 can be adjusted in concert to control the center and edge temperatures and, hence, the temperature distribution or profile of growing diamond film 60.

In an example, in response to increasing the flow rate of process gas 14, the edge and center temperatures decrease—with the center temperature decreasing by a larger magnitude than the edge temperature. To compensate for the center temperature decreasing by a larger magnitude than the edge temperature, the thermal conductivity of the cooling gas can be decreased, e.g., by raising the Ar partial pressure of the cooling gas, whereupon the edge and center temperatures increase—with the center temperature increasing by a larger magnitude than the edge temperature. The net effect of increasing the flow rate of process gas 14 AND decreasing the thermal conductivity of cooling gas 18 in this example is to exercise effective control of the actual edge temperature and/or center temperature and the temperature distribution or profile between the edge and center of the growing diamond film 60. In an example, the net effect of increasing the flow rate of process gas 14 AND decreasing the thermal conductivity of cooling gas 18 would be to maintain constant or substantially constant the actual edge temperature and center temperature and, hence, maintain constant or substantially constant the temperature distribution or profile between the edge and center of the growing diamond film 60 in spite of the changing flow rate of the process gas 14 AND the changing thermal conductivity of the cooling gas 18.

Diamond films 60 grown in accordance with the principals described herein in the first example reactor 2 shown in FIG. 1 exhibited thickness uniformity of >90%, or >95%, or >97%, or >99% across the entire substrate (as defined as 1 minus standard deviation of all measured points divided by average thickness). Low thickness variation can result in reduction in lapping time, improving throughput in post-growth fabrication of diamond film 60.

Moreover, as-grown diamond films 60 grown in accordance with the principals described herein in the first example reactor 2 shown in FIG. 1 were visually inspected and sites were chosen for the harvesting of samples with diameters ranging from 1 mm to 170 mm diameter. The chosen sites are cut using an Nd-YAG laser and further inspected for cut quality. The samples were then lapped and polished to desired thickness with a flatness of between 0 and 1.5 fringes and a roughness of between 0 nm and 10 nm. The samples were then cleaned and inspected for material properties including birefringence. In an example, the birefringence of the samples, measured at a wavelength of 632.8 nm, were between 0 and 100 nm/cm, between 0 and 80 nm/cm, between 0 and 60 nm/cm, between 0 and 40 nm/cm, between 0 and 20 nm/cm, between 0 and 10 nm/cm, or between 0 and 5 nm/cm.

As can be seen, achieving and maintaining throughout the entire MPCVD diamond film 60 growth cycle (in accordance with the principles described herein) a uniform temperature distribution across substrate 34 (or diamond film 60 growing on substrate 34) spaced from substrate holder 36 by insulating spacers 52 can yield a freestanding polycrystalline diamond film 60 with spatially uniform properties, including low thickness variation and low, spatially uniform birefringence.

In an example, a freestanding diamond film 60 grown in accordance with the principles described herein can be crack-free, can have a diameter of ≧120 mm, or ≧140 mm, or ≧160 mm, or ≧170 mm, and a thickness between 150 μm and about 3.3 mm.

Moreover, the freestanding diamond film 60 grown in accordance with the principles described herein can exhibit low residual stress leading to low deformation during post-growth processing. The freestanding diamond film 60 grown in accordance with the principles described herein can be used for the fabrication of high quality polished optical windows with the diameter between 70 mm and 160 mm and thickness between 100 μm and 3.0 mm.

It was observed that by automatically controlling the temperature distribution or profile to be constant or substantially constant between the center and the edge during growth of the diamond film 60 on substrate 34 in the first example reactor shown in FIG. 1, the grown diamond film 60 can have a low birefringence, e.g., between 0 and 100 nm/cm, or between 0 and 80 nm/cm, or between 0 and 40 nm/cm, or between 0 and 20 nm/cm, or between 0 and 10 nm/cm.

The use of electrically and thermally insulating spacers 52 avoids or eliminates the potential for arcs and, hence, hot spots between substrate 34 and substrate holder 36 during growth of diamond film 60 and reduces heat loss (cold spots) through physical contact with spacers 52. The portions (ends) of each spacers 52 that contact substrate 34 and substrate holder 36 can be polished to ensure uniform thickness variation of ±1 μm across the spacers used to space substrate 34 and substrate holder 36 via gap 38.

The embodiments have been described with reference to various examples. Modifications and alterations will occur to others upon reading and understanding the foregoing examples. Accordingly, the foregoing examples are not to be construed as limiting the disclosure.

The invention claimed is:

1. A microwave plasma reactor for the growth of polycrystalline diamond film by microwave plasma assisted chemical vapor deposition comprising:
a resonance chamber made of an electrically conductive material;
a microwave generator coupled to feed microwaves into the resonance chamber;
a plasma chamber comprising part of the resonance chamber interior space and separated from a remainder of the resonance chamber by a gas-impermeable dielectric window;
a gas control system for supplying a process gas and a cooling gas into the plasma chamber, removing gaseous byproducts from the plasma chamber, and for maintaining the plasma chamber at a lower gas pressure than the remainder of the resonant chamber;
an electrically conductive and cooled substrate holder disposed at the bottom of the plasma chamber; and
an electrically conductive substrate for growing diamond film on a top surface of the substrate that faces away from the substrate holder, wherein the substrate is disposed in the plasma chamber parallel to the substrate holder, the substrate is spaced from the substrate holder by a gap having a height d, the substrate is electrically insulated from the substrate holder, the gas control system is adapted to supply the process gas into the plasma chamber between the dielectric window and the substrate, and the gas control system is adapted to supply the cooling gas into the gap.

2. The reactor of claim 1, further including:
one or more pyrometers positioned for measuring one or more temperatures of the substrate; and
a process control system operative for controlling two or more of the following based on a temperature of the substrate measured by the one or more pyrometers:
(1) the energy of microwave power delivered to the resonance chamber;
(2) a pressure inside the plasma chamber;
(3) a flow rate of the process gas into the plasma chamber;
(4) a mixture of gases forming the process gas;
(5) a percent composition of the gases forming the process gas;
(6) a flow rate of the cooling gas;
(7) a mixture of the gases forming the cooling gas; and
(8) a percent composition of the gases forming the cooling gas.

3. The reactor of claim 1, wherein the substrate is spaced from the substrate holder by electrically nonconductive spacers.

4. The reactor of claim 3, wherein an end of each spacer has the form of a disc, a rectangle or square, or a triangle.

5. The reactor of claim 3, wherein there is a minimum of 3 spacers.

6. The reactor of claim 3, wherein an area of each spacer in contact with a bottom surface of the substrate that faces the substrate holder is <0.01% of a total surface area of the bottom surface of the substrate.

7. The reactor of claim 3, wherein a total area of the spacers in contact with a bottom surface of the substrate that faces the substrate holder is <1% of the total surface area of the bottom of the substrate.

8. The reactor of claim 3, wherein the spacers are distributed whereupon cooling gas flowing in the gap between the substrate holder and substrate has a Reynold's number of <1 such that the cooling gas flow is laminar.

9. The reactor of claim 3, wherein the spacers are made of a material having an electric resistivity >1×10⁵ Ohm-cm at 800° C.

10. The reactor of claim 3, wherein the spacers made of ceramic.

11. The reactor of claim 10, wherein the spacers made of aluminum oxide (Al₂O₃).

12. The reactor of claim 3, wherein the spacers are made of a material belonging to the group of at least one of the following: oxides, carbides and nitrides.

13. The reactor of claim 3, wherein the spacers have a thermal conductivity between one of the following:
1-50 W/m K;
10-40 W/m K; or
25-35 W/m K.

14. The reactor of claim 3, wherein at least one of the following:
each spacer is positioned between 50-80% of a radius of the substrate;
the spacers are distributed along a circumference of a single radius of the substrate; and
between a center of the substrate and the position of each spacer between the substrate and the substrate holder, a Reynolds number of the cooling gas flow through the gap is one of the following: <1; or <0.1; or <0.01.

15. The reactor of claim 1, wherein the height d of the gap between the substrate and the substrate holder is one of the following: between 0.001% and 1% of the substrate diameter, or between 0.02% and 0.5% of the substrate diameter.

16. A method of growing a diamond film in the plasma reactor of claim 1, the method comprising:
(a) providing the cooling gas into the gap between the substrate and the substrate holder;
(b) providing the process gas into the plasma chamber;
(c) supplying to the resonant chamber microwaves of sufficient energy to cause the process gas to form in the plasma chamber a plasma that heats a top surface of the substrate to an average temperature between 750° C. and 1200° C.; and
(d) in the presence of the plasma in the plasma chamber, actively controlling a temperature distribution across the top surface of the substrate and/or across a growth surface of the diamond film growing on the top surface of the substrate in response to the plasma such that the temperature distribution has less than a predetermined temperature difference between a highest temperature of the temperature distribution and a lowest temperature of the temperature distribution.

17. The method of claim 16, wherein the temperature distribution is controlled such that the as-grown diamond film has at least one of the following:
a total thickness variation (TTV) <10%, <5%, or <1%; and
a birefringence between 0 and 100 nm/cm, between 0 and 80 nm/cm, between 0 and 60 nm/cm; between 0 and 40 nm/cm, between 0 and 20 nm/cm, between 0 and 10 nm/cm, or between 0 and 5 nm/cm.

18. The method of claim 16, wherein actively controlling the temperature distribution includes controlling at least two of the following:
(1) the energy of microwave power delivered to the resonance chamber;
(2) a pressure inside the plasma chamber;
(3) a flow rate of the process gas into the plasma chamber;
(4) types of gases forming the process gas;
(5) a percent composition of the gases forming the process gas;
(6) a flow rate of the cooling gas;
(7) types of the gases forming the cooling gas; and
(8) a percent composition of the gases forming the cooling gas.

19. The method of claim 16, wherein at least one of the following:
the temperature distribution is measured between a center and an edge of the top surface of the substrate, or between a center and an edge of the growth surface of the growing diamond film, or both; and
the predetermined temperature difference between the highest and lowest temperatures of the temperature distribution is measured at the center and the edge of the top surface of the substrate, or between the center and the edge of the growth surface of the growing diamond film, or both.

20. The method of claim 16, wherein the predetermined temperature difference between the highest temperature and the lowest temperature of the temperature distribution is <10° C., <5° C., or <1° C.
